(19) United States
(12) Patent Application Publication
(10) Pub. No.: US 2026/0253637 A1
(43) Pub. Date: Aug. 27, 2026

(54) INFORMATION PROCESSING APPARATUS AND INFORMATION PROCESSING SYSTEM

(71) Applicant: Kioxia Corporation, Tokyo (JP)

(72) Inventors: Kotaro FUKUMURA, Hiratsuka (JP); Yusuke KOMANO, Yokohama (JP); Atsushi KAWASUMI, Fujisawa (JP)

(73) Assignee: Kioxia Corporation, Tokyo (JP)

(21) Appl. No.: 19/419,379

(22) Filed: Dec. 15, 2025

(30) Foreign Application Priority Data
Feb. 25, 2025 (JP) 2025-027991

(51) Int. Cl. G11C 16/04; G11C 16/28; G11C 16/30

(52) U.S. Cl. CPC G11C 16/0483; G11C 16/28; G11C 16/30

(57) ABSTRACT

An information processing apparatus has strings connected to a first wiring and respectively connected to second wirings, the strings being configured to perform an inner product operation of first data and second data each including bits, wherein each of the strings includes transistors connected in series, a threshold voltage based on the first data is set to the transistors, a voltage based on the second data is applied to each of gates of the transistors via a corresponding second wiring among the second wirings, two or more bits included in each of the first data and the second data are valid values other than 0, and each of the strings carries a current based on an inner product value of the first data respectively including different ones of the valid values and the second data respectively including different ones of the valid values to the first wiring.

### CROSS REFERENCE TO RELATED APPLICATIONS

This application is based upon and claims the benefit of priority from the prior Japanese Patent Application No. 2025-027991, filed on Feb. 25, 2025, the entire contents of which are incorporated herein by reference.

### FIELD

An embodiment of the present invention relates to an information processing apparatus and an information processing system.

### BACKGROUND

Natural language processing requires analyzing the meaning of sentences including a huge number of vocabularies and words, and when the natural language processing is performed by software, it takes a considerable time to obtain a result. Therefore, studies for performing the natural language processing with hardware are in progress.

In a case where each vocabulary constituting a sentence handled by the natural language processing is expressed by a vector, the number of dimensions of the vector is the number of vocabularies, and words included in the vocabulary are element positions of the vector, since the number of words is overwhelmingly small with respect to the number of vocabularies, a sparse vector is obtained in which a frequency at which elements of each vector are non-zero is very small. By storing such a sparse vector in a semiconductor storage device and performing an inner product operation by hardware, it is possible to determine similarity between the vocabularies. However, storing a huge number of sparse vectors in the semiconductor storage device causes poor operation efficiency and wasteful consumption of hardware resources and power.

### BRIEF DESCRIPTION OF THE DRAWINGS

FIG. 1 is a view illustrating an example in which the number of dimensions of a vector is identified by the number of vocabularies and words included in the vocabulary are identified by element positions of the vector;

FIG. 2A is a view illustrating a first example of converting a 1022-bit sparse vector into a 10-bit compressed vector;

FIG. 2B is a view illustrating a second example of converting a sparse vector in which two or more bits among 1022 bits are 1 into a 10-bit compressed vector;

FIG. 3 is a circuit diagram illustrating an example of a string used for an inner product operation;

FIG. 4 is a diagram illustrating a first transistor and a second transistor in the string;

FIG. 5 is a diagram illustrating a relationship between a threshold voltage and a gate voltage of the first transistor and the second transistor;

FIG. 6 is a flowchart illustrating a procedure of a process of searching for a match between a key and a query performed by an information processing apparatus according to an embodiment;

FIGS. 7A, 7B, and 7C are diagrams illustrating input/output information of each string;

FIG. 8 is a diagram illustrating a relationship between a threshold voltage distribution and a gate voltage of each transistor constituting each string;

FIG. 9 is a view illustrating a correspondence relationship between the number of dimensions and the number of necessary cells;

FIG. 10 is a diagram illustrating an example in which the inner product operation is performed using the string;

FIG. 11A is a diagram illustrating values of a query (Q1, Q2) and a key (K1, K2) input and set to two strings 1;

FIG. 11B is a circuit diagram of the two strings 1 in which the query (Q1, Q2) and the key (K1, K2) in FIG. 11A are input and set;

FIG. 12A is a diagram illustrating values of a query (Q1, Q2, Q3) and a key (K1, K2, K3) input and set to three strings 1;

FIG. 12B is a circuit diagram of the three strings 1 in which the query (Q1, Q2, Q3) and the key (K1, K2, K3) in FIG. 12A are input and set;

FIG. 13 is a diagram illustrating combinations of compressed vectors each including one valid value;

FIG. 14 is a circuit diagram of a plurality of strings configured using a plurality of memory cell transistors in a memory cell array;

FIG. 15A is a diagram illustrating values of a query (Q1, Q2) and a key (K1, K2) input and set to four strings according to a first example;

FIG. 15B is a circuit diagram of the four strings according to the first example in which the query (Q1, Q2) and the key (K1, K2) in FIG. 15A are input and set;

FIG. 16A is a diagram illustrating values of a query (Q1, Q2) and a key (K1, K2) input and set to four strings according to a second example;

FIG. 16B is a circuit diagram of the four strings according to the second example in which the query (Q1, Q2) and the key (K1, K2) in FIG. 16A are input and set;

FIG. 17A is a diagram illustrating values of a query (Q1, Q2) and a key (K1, K2) input and set to four strings according to a third example;

FIG. 17B is a circuit diagram of the four strings according to the third example in which the query (Q1, Q2) and the key (K1, K2) in FIG. 17A are input and set;

FIG. 18A is a diagram illustrating values of a query (Q1, Q2) and a key (K1, K2) input and set to four strings according to a fourth example;

FIG. 18B is a circuit diagram of the four strings according to the fourth example in which the query (Q1, Q2) and the key (K1, K2) in FIG. 18A are input and set;

FIG. 19 is a view illustrating a correspondence relationship between the number of all dimensions of a key and a query and the number of valid values included in the key and the query;

FIGS. 20A, 20B, and 20C are diagrams each illustrating a memory area including a string secured on the memory cell array according to the number of valid values included in each sparse vector of a key and a query;

FIG. 21A is a diagram for describing an example in which the inner product operation is performed in a time-division manner by using a limited number of strings a plurality of times;

FIG. 21B is a diagram illustrating an example in which FIG. 21A is further embodied; and

FIG. 22 is a block diagram illustrating a schematic configuration of an information processing system including the information processing apparatus according to the embodiment.

### DETAILED DESCRIPTION

In general, according to the embodiment, an information processing apparatus comprises a plurality of strings connected to a first wiring and respectively connected to a plurality of second wirings. The plurality of strings are configured to perform an inner product operation of first data and second data each including a plurality of bits. Each of the plurality of strings includes a plurality of transistors connected in series. A threshold voltage based on the first data is set to the plurality of transistors. A voltage based on the second data is applied to each of gates of the plurality of transistors via a corresponding second wiring among the second wirings. Two or more bits included in each of the first data and the second data are valid values other than 0. Each of the plurality of strings carries a current based on an inner product value of the first data respectively including different ones of the valid values and the second data respectively including different ones of the valid values to the first wiring.

Hereinafter, embodiments of an information processing apparatus and an information processing system will be described with reference to the drawings. Although main components of the information processing apparatus and the information processing system will be mainly described below, the information processing apparatus and the information processing system may have components and functions that are not illustrated or described. The following description does not exclude the components and functions that are not illustrated or described.

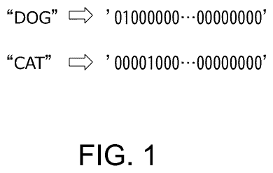

FIG. 1 is a view illustrating an example in which each vocabulary included in some sentence to be analyzed by natural language processing is expressed by a vector, the number of dimensions of the vector is identified by the number of vocabularies, and words included in the vocabulary are identified by element positions of the vector. FIG. 1 illustrates an example in which a case where only the second element from the left of a vector representing a certain vocabulary is 1 represents a “dog”, and a case where only the fifth element from the left of the vector is 1 represents a “cat”. The number of elements of the vector in FIG. 1 is, for example, 1024. Among vectors each having many elements, a vector in which only one element at most is 1 as described above is referred to as a sparse vector.

The sparse vector is identified by the element position of 1, and thus can be converted into a compressed vector representing the element position of 1 in the sparse vector. For example, in a case where the sparse vector is converted into a 10-bit compressed vector and a compressed vector “0000000000” is not defined, a 1022-bit sparse vector can be converted into a 10-bit compressed vector.

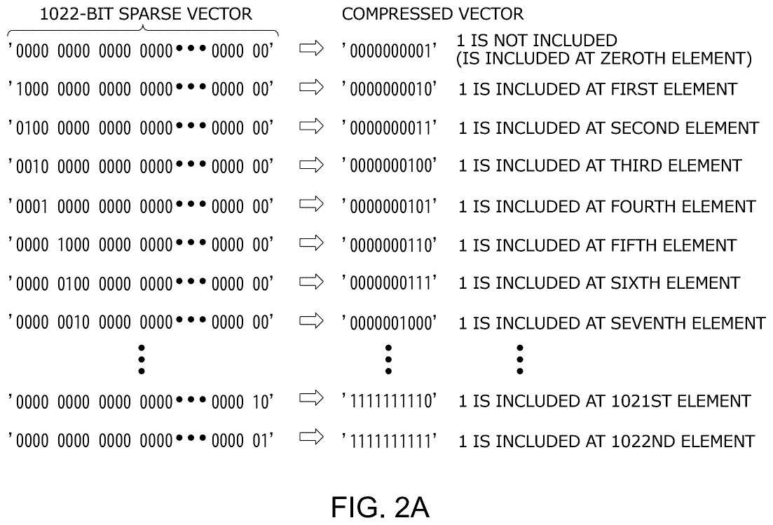

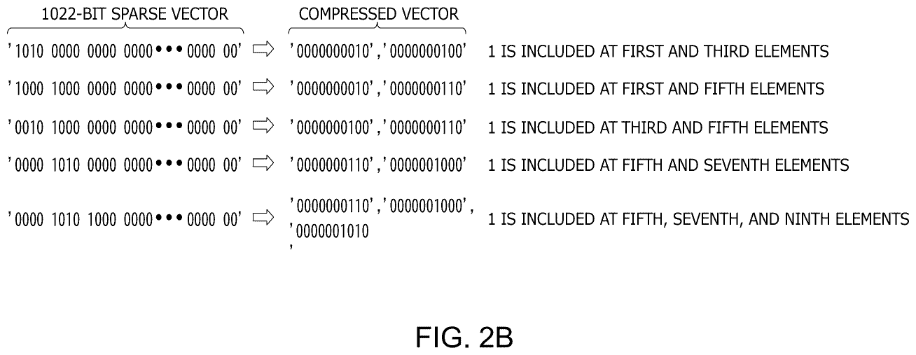

FIG. 2A is a view illustrating a first example of converting a sparse vector in which at most one bit among 1022 bits is 1 into a 10-bit compressed vector. In the first example of FIG. 2A, when all elements of the sparse vector are zero, the sparse vector is converted into a compressed vector “0000000001”. When only the first element of the sparse vector is 1, the sparse vector is converted into a compressed vector “0000000010”. When only the second element of the sparse vector is 1, the sparse vector is converted into a compressed vector “0000000011”.

Hereinafter, similarly, as the order of the element position of 1 of the sparse vector increases, the 10-bit compressed vector is increased each by one bit from a lower-order bit side to a higher-order bit side. As a result, when only the 1021st element of the sparse vector is 1, the sparse vector is converted into a compressed vector “1111111110”. When only the 1022nd element of the sparse vector is 1, the sparse vector is converted into a compressed vector “1111111111”.

FIG. 2B is a view illustrating a second example of converting a sparse vector in which two or more bits among 1022 bits are 1 into a 10-bit compressed vector. When the first and third elements of the sparse vector are 1, the sparse vector is converted into two compressed vectors “0000000010” and “0000000100”. When the first and fifth elements of the sparse vector are 1, the sparse vector is converted into two compressed vectors “0000000010” and “0000000110”. When the third and fifth elements of the sparse vector are 1, the sparse vector is converted into two compressed vectors “0000000100” and “0000000110”. When the fifth and seventh elements of the sparse vector are 1, the sparse vector is converted into two compressed vectors “0000000110” and “0000001000”. When the fifth, seventh, and ninth elements of the sparse vector are 1, the sparse vector is converted into three compressed vectors “0000000110”, “0000001000”, and “0000001010”.

As described above, by converting a sparse vector into a compressed vector representing the element position of 1 of the sparse vector, the number of elements of the sparse vector can be compressed to about 1/10.

By performing an inner product operation between two sparse vectors, it is possible to determine whether each pair of elements of the two sparse vectors match based on an inner product value. In the present specification, for performing the inner product operation between the two sparse vectors, the two sparse vectors are converted into two compressed vectors, and the inner product operation between the two compressed vectors is performed. The inner product operation between the two compressed vectors can be performed by using a string in which a plurality of transistors are cascode-connected. In the present specification, cascode connection of a plurality of transistors may be referred to as series connection.

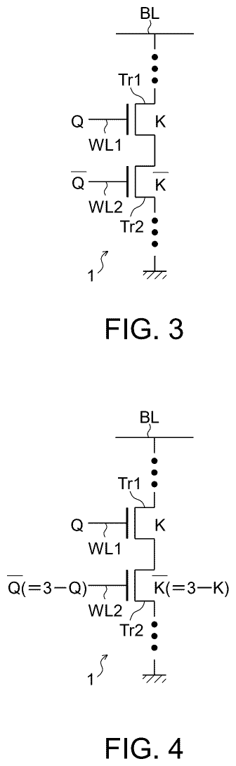

FIG. 3 is a circuit diagram illustrating an example of the string used for the inner product operation. A string 1 illustrated in FIG. 3 is, for example, a part of a memory cell array in a semiconductor storage device.

Here, a semiconductor storage device is, for example, a nonvolatile memory such as a NAND flash memory, a resistive random access memory (ReRAM), or a phase-change memory (PCM). Alternatively, the semiconductor storage device described above may be a volatile memory such as a dynamic RAM (DRAM) or a static RAM (SRAM). In the present specification, an example of using the string 1 of the NAND flash memory will be mainly described, but the string 1 may be configured using a semiconductor storage device other than the NAND flash memory.

The string 1 illustrated in FIG. 3 includes a plurality of cascode-connected transistors. FIG. 3 illustrates an example of the string 1 including a first transistor Tr1 and a second transistor Tr2 cascode-connected. The string 1 can be configured by cascode-connecting any number of transistors in addition to the first transistor Tr1 and the second transistor Tr2.

One end of the string 1 is connected to a bit line (first wiring) BL. Different word lines (second wirings) WL1 and WL2 are connected to gates of the first and second transistors Tr1 and Tr2 in the string 1. In the present specification, the plurality of word lines WL1, WL2, and the like may be collectively referred to as a word line WL.

The plurality of transistors in the string 1 store data supplied via the bit line BL in a state where the word line WL connected to each gate is set to a predetermined potential level. For example, in the case of the string 1 of the NAND flash memory, each transistor in the string 1 stores a charge corresponding to data in a floating gate or a charge storage film. By storing data in the transistor, a threshold voltage of the transistor changes. When the threshold voltage of the transistor changes, a gate potential level at which the transistor is turned on changes.

Among the plurality of transistors in each string 1, the first transistor Tr1 and the second transistor Tr2 are used to store a key K consisting of a plurality of bits. In the present embodiment, it is assumed that each bit of the key K is multi-valued data, but first, an example in which each bit of the key K is binary (0 or 1) will be described with reference to FIG. 3.

The value of each bit of the key K is stored in the first transistor Tr1 and the second transistor Tr2 in the separate strings 1. The first transistor Tr1 in each string 1 stores a value of a corresponding bit of the key K, and the second transistor Tr2 cascode-connected to the first transistor Tr1 stores a value having a complementary relationship with the value of the corresponding bit of the key K. The value having the complementary relationship is bit-inverted data. For example, when the first transistor Tr1 stores 0, the second transistor Tr2 stores 1. In the present specification, the key K consisting of a plurality of bits is referred to as first data, and complement data of the key K is referred to as second data.

In the present specification, the fact that the first transistor Tr1 stores 0 means that a threshold voltage of the first transistor Tr1 is set to 0. In practice, the threshold voltage of the first transistor Tr1 is set to a potential level corresponding to 0, but in the present specification, it is assumed that the threshold voltage is set to 0 for the sake of simplicity.

Third data and fourth data are supplied to the two word lines WL1 and WL2 connected to the gates of the first transistor Tr1 and the second transistor Tr2 among the plurality of transistors in the string 1, respectively. The third data and the fourth data each consist of a plurality of bits, and the fourth data is data having a complementary relationship with the third data. That is, data obtained by inverting each bit of the third data is the fourth data. Each bit of the third data and the fourth data is assumed to be multi-valued data having a potential level of three values or more, but first, an example in which each bit of the third data and the fourth data is binary (0 or 1) will be described. The third data is a corresponding bit of a query Q. Each bit of the query Q is supplied on a different word line.

The information processing apparatus according to the present embodiment grasps whether the query Q input from the outside matches with the key K stored in the plurality of strings 1 by the inner product operation, and outputs the result of the inner product operation via the bit line BL.

The query Q and the key K each consist of a plurality of bits, and are compared using the first transistor Tr1 and the second transistor Tr2 corresponding to each bit. In the present specification, the key K is referred to as the first data, and the query Q is referred to as the third data. In addition, data having a complementary relationship with the first data is referred to as the second data, and data having a complementary relationship with the third data is referred to as the fourth data.

As described above, a corresponding bit of the key K (first data) stored in the first transistor Tr1 and a corresponding bit of a key/K (second data) stored in the second transistor Tr2 have a complementary relationship with each other. For example, when the corresponding bit of the key K is “0”, the corresponding bit of the key/K is “1”. As described above, corresponding bits of the first data and the second data having a complementary relationship with each other are written in the first transistor Tr1 and the second transistor Tr2, so that a threshold voltage of the first transistor Tr1 and a threshold voltage of the second transistor Tr2 have different values. In the present specification, the threshold voltage of the first transistor Tr1 is referred to as a first threshold voltage, and the threshold voltage of the second transistor Tr2 is referred to as a second threshold voltage.

There is a case where a plurality of sets each including the first transistor Tr1 and the second transistor Tr2 are connected in series in the string 1. In this case, threshold voltages having a complementary relationship with each other are set to the first transistor Tr1 and the second transistor Tr2 of the same set based on the first data, and voltages having a complementary relationship with each other are applied to gates of the first transistor Tr1 and the second transistor Tr2 of the same set based on the second data.

More specifically, threshold voltages based on a corresponding bit value of the first data and an inverted bit value thereof are set to the first transistor Tr1 and the second transistor Tr2 of the same set, and voltages based on a corresponding bit value of the second data and an inverted bit value thereof are applied to the gates of the first transistor Tr1 and the second transistor Tr2 of the same set.

Although FIG. 3 illustrates an example in which each bit of the query Q and the key K is binary data, simply comparing binary data of each bit only results in a simple comparison between binary data. In recent nonvolatile memories, multi-valued data of three or more values can be stored in a memory cell, and a storage capacity of the nonvolatile memory is increased. By using the nonvolatile memory capable of storing such multi-valued data, even when each bit of the query Q and the key K is multi-valued data, the query Q and the key K can be compared, and the application range of the information processing apparatus according to the present embodiment is widened.

FIG. 4 is a diagram illustrating the first transistor Tr1 and the second transistor Tr2 in the string 1 in a case where each bit of the query Q and the key K is multi-valued data of four values consisting of two bits. In this case, each bit of the query Q and the key K can take four potential levels consisting of two bits. The key K (the first threshold voltage of the first transistor Tr1) stored in the first transistor Tr1 and the key/K (the second threshold voltage of the second transistor Tr2) stored in the second transistor Tr2 have a complementary relationship with each other, and when the first threshold voltage of the first transistor Tr1 is K, the second threshold voltage of the second transistor Tr2 is 3-K.

Similarly, since the query Q input to the gate of the first transistor Tr1 and a query/Q input to the gate of the second transistor Tr2 have a complementary relationship with each other, when the query Q input to the gate of the first transistor Tr1 is Q, the query/Q input to the gate of the second transistor Tr2 is represented by 3-Q.

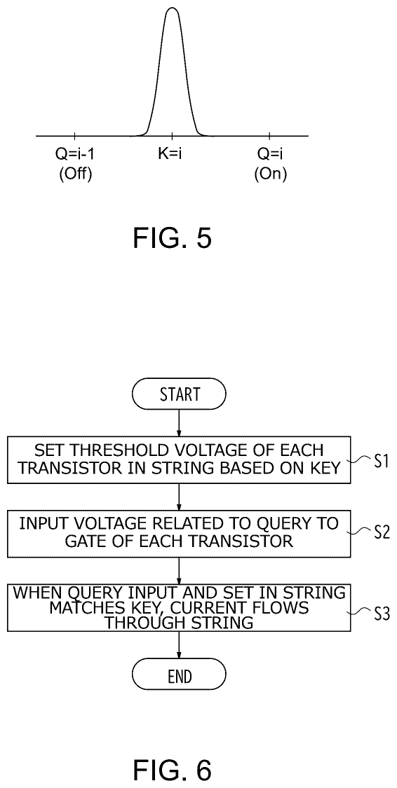

FIG. 5 is a diagram illustrating a relationship between the threshold voltage and the gate voltage of the first transistor Tr1 and the second transistor Tr2. The first threshold voltage of the first transistor Tr1 in each string 1 is a value based on the multi-valued data of the corresponding bit of the key K input via the bit line BL. Since a voltage level of the threshold voltage slightly varies for each transistor, a potential level of the first threshold voltage of the first transistor Tr1 varies within a predetermined range as illustrated in FIG. 5. This variation range is called a threshold voltage distribution. The first transistor Tr1 is turned on when a potential level of the query Q input to the gate of the first transistor Tr1 is larger than the threshold voltage distribution, and is turned off when the potential level of the query Q is smaller than the threshold voltage distribution. The same applies to the second transistor Tr2.

From FIGS. 4 and 5, the first transistor Tr1 and the second transistor Tr2 are turned on only when both the following Equations (1) and (2) are satisfied.

$$Q \geq K \qquad ( 1 )$$

$$3 - Q \geq 3 - K \qquad ( 2 )$$

Equation (3) is obtained by modifying Equation (2).

$$Q \leq K \qquad ( 3 )$$

A condition that satisfies both Equation (1) and Equation (3) is represented by Equation (4).

$$Q = K \qquad ( 4 )$$

As described above, the first transistor Tr1 and the second transistor Tr2 in each string 1 are turned on only when pieces of the multi-valued data of the corresponding bits of the query Q and the key K match.

The information processing apparatus according to the embodiment performs natural language processing on a sentence used by a human in daily life to generate the above-described sparse vector, and converts the generated sparse vector into a compressed vector. The compressed vector represents a word included in a vocabulary, and vocabularies and words included in various sentences are learned using the compressed vectors. Since it is necessary to handle a huge amount of sentences, the learning may be performed by a cloud server or the like provided separately from the information processing apparatus. A key for a query is generated based on a result of the learning. The key is, for example, information representing a word.

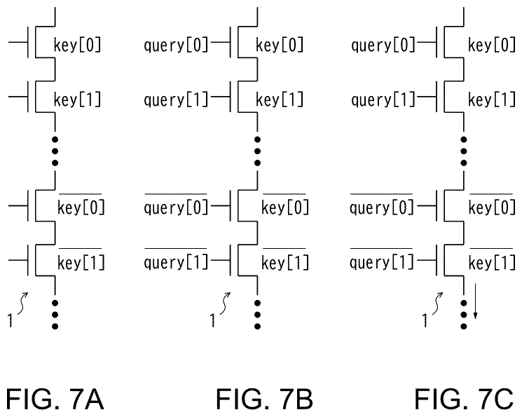

FIG. 6 is a flowchart illustrating a procedure of a process of searching for a match between a key and a query performed by the information processing apparatus according to the embodiment. FIGS. 7A, 7B, and 7C included in FIG. 7 are diagrams illustrating input/output information of each string.

The information processing apparatus according to the embodiment sets threshold voltages of a plurality of transistors constituting the string 1 based on a key obtained by learning (step S1). FIG. 7A illustrates an example of setting the threshold voltages related to the key in each string 1. Each string includes a first transistor in which a threshold voltage related to keys key [0], key [1], and the like is set, and a second transistor in which a threshold voltage related to complements/key [0],/key [1], and the like of the keys key [0], key [1], and the like is set. Note that a complement of a key or a query is expressed by adding a bar above a symbol of the key or the query in the present drawings, and is expressed by adding a slash before the symbol in the present specification. The threshold voltage related to the key set to each transistor is fixed until the key is updated by relearning.

Next, the information processing apparatus inputs a query corresponding to a question input from the outside to each of gates of the plurality of transistors constituting the string 1 via a word line (step S2). As a result, each of the transistors compares a gate voltage related to the query with the threshold voltage related to the key. FIG. 7B illustrates an example in which queries query [0] and the like are supplied to the gates of the respective first transistors constituting the string 1, and/query [0] and the like are supplied to the gates of the respective second transistors. If the gate voltage and the threshold voltage match in all the transistors constituting the string 1, a current flows through the string 1 as illustrated in FIG. 7C (step S3). If there is even one transistor in which the gate voltage and the threshold voltage do not match in the string 1, no current flows through the string 1. The information processing apparatus determines that the query and the key match when the current flows through the string 1, and determines that the query and the key do not match when the current does not flow through the string 1.

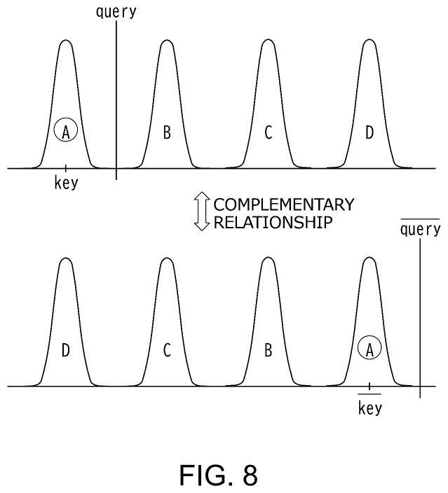

FIG. 8 is a diagram illustrating a relationship between a threshold voltage distribution and the gate voltage of each of the transistors constituting the string 1. The upper part of FIG. 8 illustrates the relationship between the threshold voltage distribution and the gate voltage of the first transistor in the string 1, and the lower part of FIG. 8 illustrates the relationship between the threshold voltage distribution and the gate voltage of the second transistor in a complement relationship with the first transistor in the string 1.

FIG. 8 illustrates an example in which a key matches with a query when the key is A. As illustrated in FIG. 8, when the query and the key match, the gate voltages of the first transistor and the second transistor are set to be larger than the threshold voltages. As a result, the first transistor and the second transistor are turned on, and a current flows through the string 1.

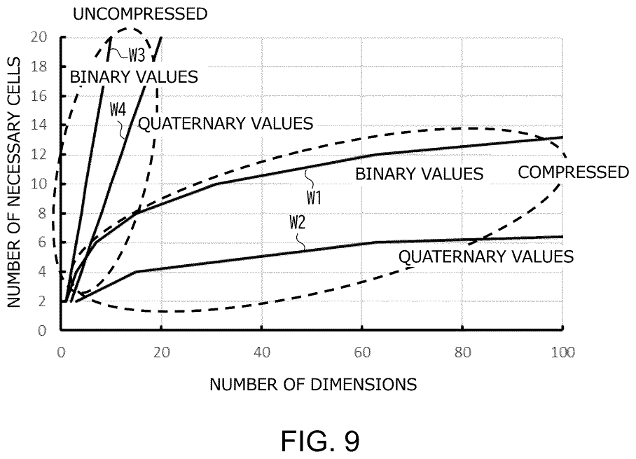

FIG. 9 is a view illustrating a correspondence relationship between the number of dimensions and the number of necessary cells in a compressed vector obtained by compressing a sparse vector and an uncompressed vector obtained by not compressing the sparse vector. FIG. 9 illustrates a correspondence relationship W1 of a binary compressed vector, a correspondence relationship W2 of a quaternary compressed vector, a correspondence relationship W3 of a binary uncompressed vector, and a correspondence relationship W4 of a quaternary uncompressed vector. The number of necessary cells refers to the number of transistors constituting the string 1 necessary for performing the inner product operation.

As illustrated in FIG. 9, a degree of increase in the number of necessary cells with respect to increase in the number of dimensions is smaller in the compressed vectors than in the uncompressed vectors. In addition, the degree of increase in the number of necessary cells with respect to increase in the number of dimensions is smaller in the quaternary compressed vector than in the binary compressed vector. In the uncompressed vectors, the number of necessary cells increases in proportion to increase in the number of dimensions, and the ratio of the increase in the number of necessary cells to the increase in the number of dimensions is larger in the quaternary uncompressed vector than in the binary uncompressed vector.

As described above, as compared with the uncompressed vector, the inner product operation of the sparse vector can be performed with a smaller number of cells in the compressed vector, and the inner product operation can be more efficiently performed with multi-valued data.

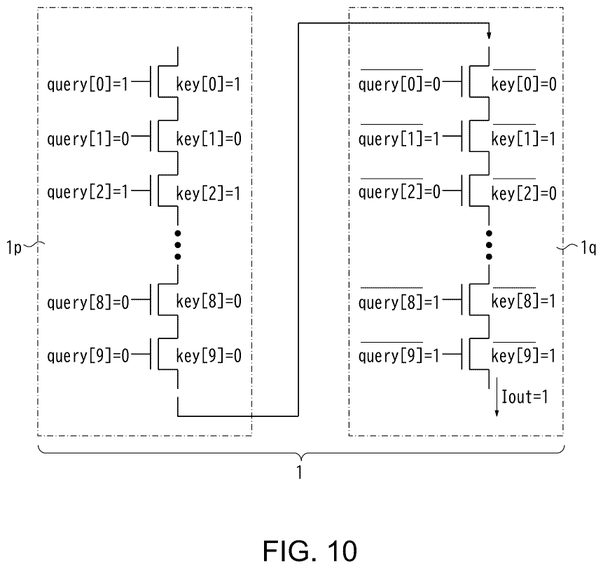

FIG. 10 is a diagram illustrating an example in which the inner product operation is performed using the string 1. FIG. 10 illustrates an example in which each of transistors Tr0 to Tr9 constituting the string 1 stores binary values. The string 1 of FIG. 10 has a string portion 1p and a string portion 1q connected in series. The same number of transistors Tr0 to Tr9 are cascode-connected to each of the string portion 1p and the string portion 1q. Threshold voltages and gate voltages of the transistors Tr0 to Tr9 in the string portion 1p are in a complementary relationship with those of the transistors Tr0 to Tr9 in the string portion 1q, respectively.

FIG. 10 illustrates an example in which a key, related to a compressed vector “0000000101” obtained by compressing a sparse vector in which the fourth element is 1, is set to the threshold voltage of each of the transistors Tr to Tr9 of the string 1, and a query, related to the compressed vector “0000000101”, is applied to the gate of each of the transistors Tr0 to Tr9 of the string 1.

More specifically, the threshold voltage related to the compressed vector “0000000101” is set to each of the transistors Tr0 to Tr9 of the string portion 1p, and a threshold voltage, related to “1111111010” that is a complement of the compressed vector “0000000101”, is set to each of the transistors Tr0 to Tr9 of the string portion 1q. In addition, a voltage related to the compressed vector “0000000101” is applied to the gate of each of the transistors Tr0 to Tr9 of the string portion 1p via a word line, and a voltage related to “1111111010” that is the complement of the compressed vector “0000000101” is applied to the gate of each of the transistors Tr0 to Tr9 of the string portion 1q.

A current flows through the string portion 1p and the string portion 1q only when the query and the key match.

In the present specification, an element of 1 included in a sparse vector is referred to as a valid value. The sparse vector does not necessarily include at most one valid value, and may include two or more valid values. When the sparse vector includes two or more valid values, a correct inner product value may not be obtained in the string 1 of FIG. 10.

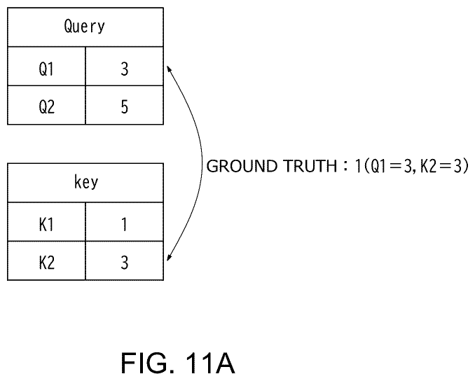

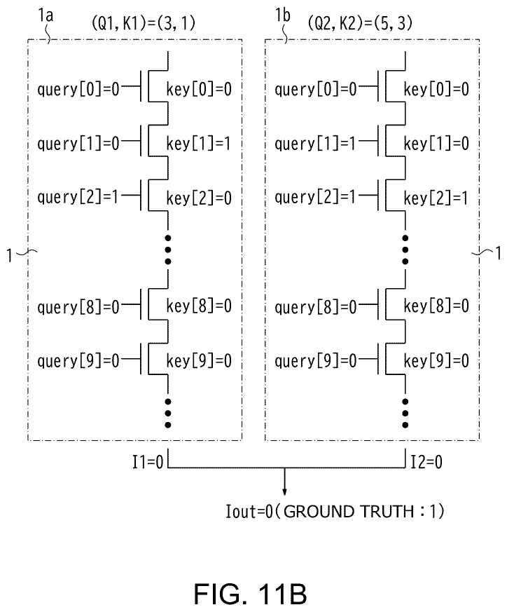

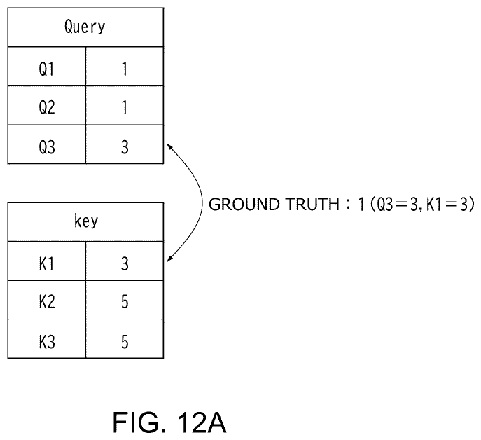

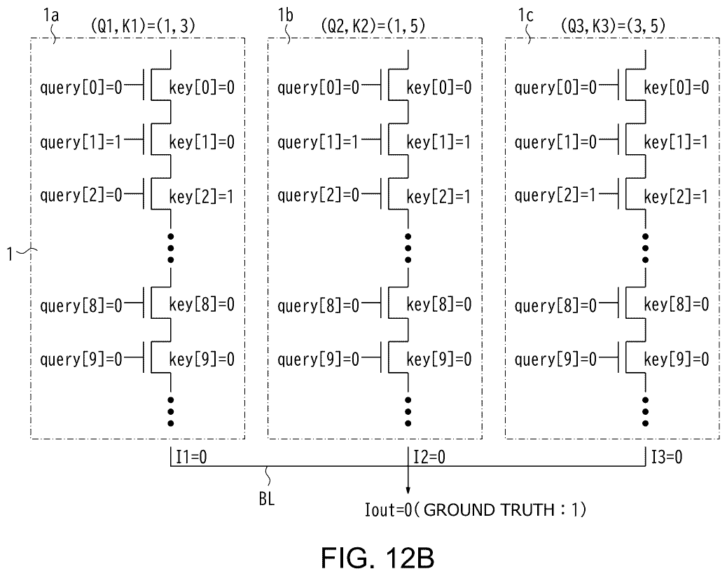

FIGS. 11A and 11B are diagrams illustrating an example in which the inner product operation of two compressed vectors corresponding to two sparse vectors each including two valid values is performed using two strings 1 connected in parallel. FIG. 11A is a diagram illustrating values of a query (Q1, Q2) and a key (K1, K2) input and set to the two strings 1. FIG. 11B is a circuit diagram of the two strings 1 in which the query (Q1, Q2) and the key (K1, K2) of FIG. 11A are input and set. The compressed vector includes a plurality of bits representing, in a binary number, a bit position of a valid value in the sparse vector including bits of 0 other than the valid value. A threshold voltage based on a valid value of one compressed vector corresponding to the key is set to each of the transistors Tr0 to Tr9 of the two strings 1. In addition, a voltage based on a valid value of the other compressed vector corresponding to the query is applied to the gate of each of the transistors Tr0 to Tr9 of the two strings 1 via a word line. In the two strings 1 illustrated in FIG. 11B, a first transistor array in which the query is input to the gate and the key is set as the threshold voltage and a second transistor array in which a complement of the query is input to the gate and a complement of the key is set as the threshold voltage are connected in series, but the expression of the second transistor array is omitted in FIG. 11B. Similarly, the expression of the second transistor array in each string 1 is omitted in FIGS. 12A to 19 described later.

In FIG. 11B, the two strings 1 connected in parallel are referred to as a first string 1a and a second string 1b. FIG. 11A illustrates an example in which two valid values (K1, K2) of one compressed vector corresponding to the key are (1, 3), and two valid values (Q1, Q2) of the other compressed vector corresponding to the query are (3, 5). In this case, since both the key and the query include the valid value=3, essentially, a current should flow through the string 1, but as illustrated in FIG. 11B, there may be a case where the current does not flow through the string 1.

FIG. 11B illustrates an example of comparing (Q1, K1) in the first string 1a and comparing (Q2, k2) in the second string 1b. In this example, a threshold voltage related to the valid value K1=1 is set to each of the transistors Tr0 to Tr9 of the first string 1a, and a threshold voltage related to the valid value K2=3 is set to each of the transistors Tr0 to Tr9 of the second string 1b. In addition, a voltage related to the valid value Q1=3 is applied to the gate of each of the transistors Tr to Tr9 of the first string 1a, and a voltage related to the valid value Q2=5 is applied to the gate of each of the transistors Tr0 to Tr9 of the second string 1b.

In the case of FIG. 11B, in the first string 1a, since the compressed vector corresponding to the sparse vector of the key=1 is compared with the compressed vector corresponding to the sparse vector of the query=3, the key and the query do not match, so that no current flows through the first string 1a. In addition, in the second string 1b, since the compressed vector corresponding to the sparse vector of the key=3 is compared with the compressed vector corresponding to the sparse vector of the query=5, the key and the query do not match, so that no current flows through the second string 1b.

As described above, it is conceivable to compare a query with a key using the plurality of strings 1 to perform the inner product operation of two sparse vectors each including a plurality of valid values, but there may be a case where the inner product operation of the two sparse vectors cannot be correctly performed because results of the inner product operation vary depending on which valid value is related to a threshold voltage set for each transistor in any one of the strings 1 and which valid value is related to a voltage applied to a gate of each transistor in any one of the strings 1.

FIGS. 12A and 12B are diagrams illustrating an example in which the inner product operation of two compressed vectors corresponding to two sparse vectors each including two valid values is performed using three strings 1 connected in parallel. FIG. 12A is a diagram illustrating values of a query (Q1, Q2, Q3) and a key (K1, K2, K3) input and set to the three strings 1. FIG. 12B is a circuit diagram of the three strings 1 in which the query (Q1, Q2, Q3) and the key (K1, K2, K3) in FIG. 12A are input and set.

FIG. 12A illustrates an example in which three valid values (K1, K2, K3) of one compressed vector corresponding to the key are (3, 5, 5), and three valid values (Q1, Q2, Q3) of the other compressed vector corresponding to the query are (1, 1, 3). In this case, since both the key and the query include the valid value=3, essentially, a current should flow through the string 1, but as illustrated in FIG. 12B, there may be a case where the current does not flow through the string 1.

Hereinafter, the three strings 1 connected in parallel in FIG. 12B are referred to as first to third strings 1a, 1b, and 1c. FIG. 12B illustrates an example of comparing (Q1, K1) in the first string 1a, comparing (Q2, K2) in the second string 1b, and comparing (Q3, K3) in the third string 1c. In this example, a threshold voltage related to the valid value K1=3 is set for each transistor of the first string 1a, and a threshold voltage related to the valid value K2=5 is set for each transistor of the second string 1b and the third string 1c. In the example of FIG. 12B, a voltage related to the valid value Q1=1 is applied to a gate of each transistor of the first string 1a and the second string 1b, and a voltage related to the valid value Q2=3 is applied to a gate of each transistor of the third string 1c.

In the case of FIG. 12B, in the first string 1a, since the compressed vector corresponding to the sparse vector of the key=3 is compared with the compressed vector corresponding to the sparse vector of the query=1, the key and the query do not match, so that no current flows through the first string 1a. In addition, in the second string 1b, since the compressed vector corresponding to the sparse vector of the key=5 is compared with the compressed vector corresponding to the sparse vector of the query=1, the key and the query do not match, so that no current flows through the second string 1b. In addition, in the third string 1c, since the compressed vector corresponding to the sparse vector of the key=5 is compared with the compressed vector corresponding to the sparse vector of the query=3, the key and the query do not match, so that no current flows through the third string 1c.

As illustrated in FIGS. 11B and 12B, when the inner product operation of the two compressed vectors corresponding to the two sparse vectors each including the two valid values is performed using the three or less strings 1, there is a possibility that a correct inner product value cannot be calculated.

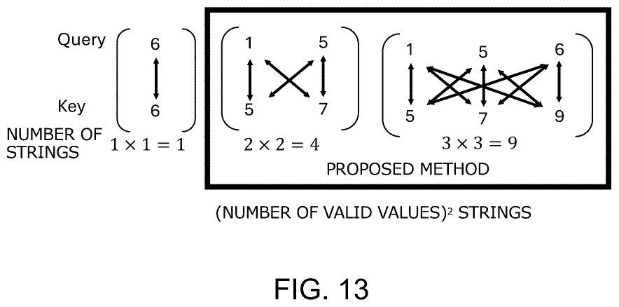

FIG. 13 is a diagram illustrating combinations of compressed vectors each including one valid value when the number of valid values included in a sparse vector is 1 to 3. As illustrated in FIG. 13, in a case where the number of valid values included in the sparse vector is 1, the number of combinations of two compressed vectors corresponding to a key and a query is 1, and a correct inner product value is obtained with one string 1. In a case where the number of valid values included in the sparse vector is 2, the number of combinations of two compressed vectors corresponding to a key and a query is 2×2=4, and a correct inner product value is obtained with four strings 1. The number of combinations of three compressed vectors corresponding to the key and the query is 3×3=9, and a correct inner product value is obtained with nine strings 1.

As described above, in a case where the number of valid values included in a sparse vector is n (n is an integer of 1 or more), the number of strings 1 for obtaining a correct inner product value is the square of n.

How many valid values are included in a sparse vector can be obtained, for example, by learning valid values included in a large number of sparse vectors obtained by natural language processing. This learning requires enormous arithmetic processing capacity, and thus may be performed by a device (for example, a server) different from the information processing apparatus according to the embodiment, and information on valid values and keys obtained by the learning may be input to the information processing apparatus according to the embodiment.

The information processing apparatus according to the embodiment secures the strings 1 as many as the square of the number of valid values on a memory cell array based on the valid values included in a sparse vector. The strings 1 can be configured using, for example, the memory cell array of a nonvolatile memory such as a NAND flash memory, and a memory area including the strings 1 as many as the square of the number of valid values is secured on the memory cell array.

In the information processing apparatus according to the embodiment, for performing search for a match between a key and a query, the number of the strings 1 corresponding to the number of valid values included in the two sparse vectors of the key and the query is secured on the memory cell array, and the search for the match is performed in each of the strings 1 for all combinations of a compressed vector for the key and a compressed vector for the query, the compressed vectors including mutually different valid values. Since these strings 1 are connected to a common bit line and a current flows through the string 1 in which the key and the query match, results of the search for the match between the key and the query can be acquired based on the currents flowing from all the strings 1 to the bit line.

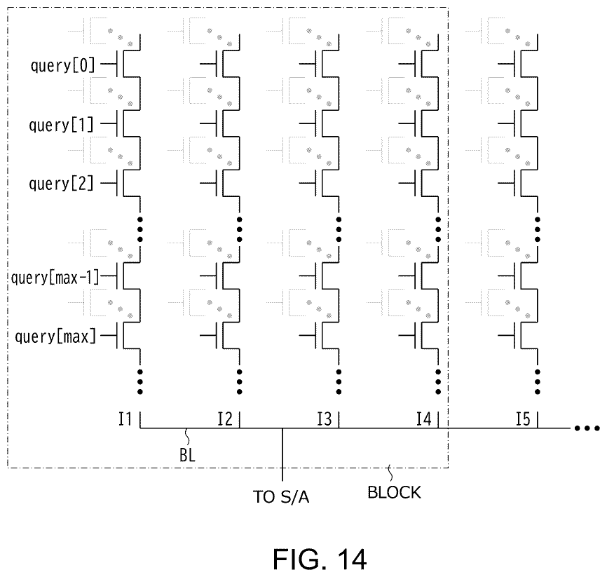

FIG. 14 is a circuit diagram of a plurality of strings 1 configured using a plurality of memory cell transistors (hereinafter, simply referred to as transistors) in a memory cell array. For example, when the inner product operation of two sparse vectors each including two valid values is performed, four strings 1 are required. Therefore, in FIG. 14, a memory area including four strings 1 connected to one bit line is set as one block, and the inner product operation is performed for each block. A plurality of bit lines are arranged in one block illustrated in FIG. 14, and four strings 1 are connected to each bit line. In addition, a plurality of strings 1 corresponding to a plurality of blocks are connected to each bit line.

All currents flowing through four strings 1 of the same block flow through a corresponding bit line. Each bit line is connected to a sense amplifier (S/A). The sense amplifier determines whether a key and a query match based on the current flowing through each bit line. For example, when the inner product operation of two sparse vectors each including two valid values is performed, in a case where both of the two valid values match between the query corresponding to one sparse vector and the key corresponding to the other sparse vector, a current that is twice as large as that in a case where only one of the two valid values matches flows through the bit line. When neither of the two valid values matches, no current flows through the bit line. As described above, the sense amplifier can specify how many valid values of the key and the query match based on the current flowing through the bit line.

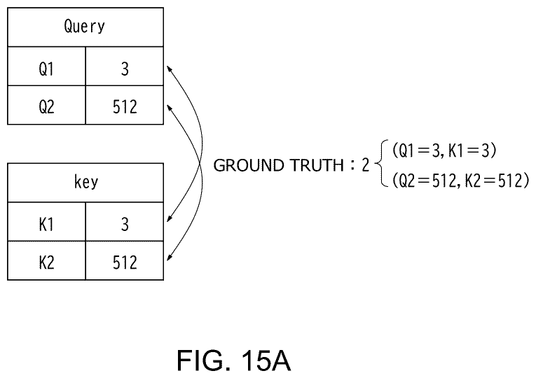

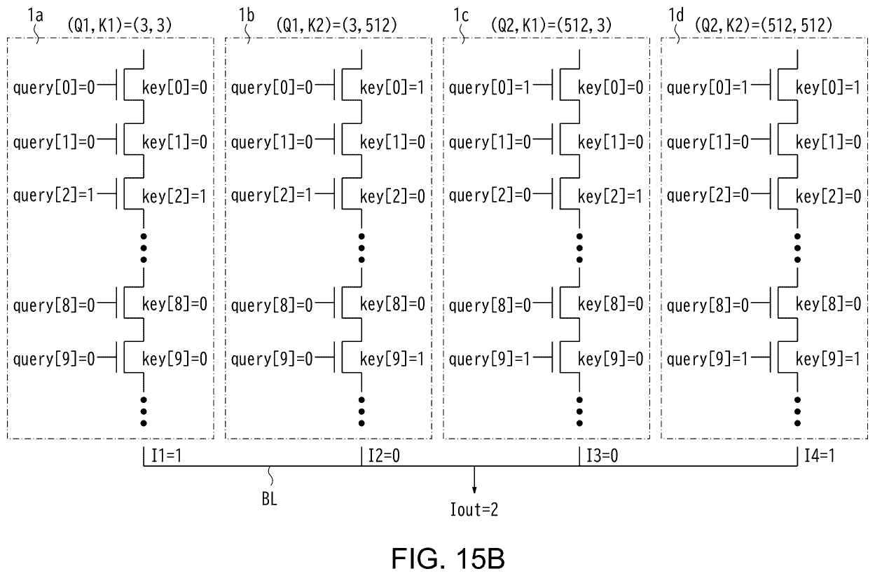

FIGS. 15A to 18B are diagrams illustrating first to fourth examples of the inner product operation of two compressed vectors corresponding to two sparse vectors each including two valid values. In the first to fourth examples, 2×2=4 strings 1 (hereinafter, referred to as first to fourth strings 1a to 1d) are prepared, a threshold voltage of each transistor of each of the strings 1 is set based on one compressed vector corresponding to a key, and a voltage based on the other compressed vector corresponding to a query is applied to a gate of each transistor of each of the strings 1. More specifically, the match search is performed in the four strings 1 for all combinations of two compressed vectors for the key each including one different valid value and two compressed vectors for the query each including one different valid value. In FIGS. 15A to 18B, it is assumed that each transistor in each of the strings 1 stores a binary value.

In the first example of FIGS. 15A and 15B, each of the key and the query has valid values of 3 and 512. This is expressed as (Q1, Q2)=(3, 512) and (K1, K2)=(3, 512) in the present specification. FIG. 15A is a diagram illustrating values of the query (Q1, Q2) and the key (K1, K2) input and set to the four strings 1 according to the first example. FIG. 15B is a circuit diagram of the four strings 1 according to the first example in which the query (Q1, Q2) and the key (K1, K2) in FIG. 15A are input and set. As illustrated in FIG. 15A, since each of the key and the query has two valid values in the first example, all combinations of the key and the query are (Q1, K1)=(3, 3), (Q1, K2)=(3, 512), (Q2, K1)=(512, 3), and (Q2, K2)=(512, 512).

In the first example, (Q1, K1)=(3, 3) is compared in the first string 1a, (Q1, K2)=(3, 512) is compared in the second string 1b, (Q2, K1)=(512, 3) is compared in the third string 1c, and (Q2, K2)=(512, 512) is compared in the fourth string 1d.

As illustrated in FIG. 15B, in the first example, a threshold voltage related to the key K1=3 is set to each transistor of the first string 1a, and a voltage related to the query Q1=3 is applied to the gate of each transistor of the first string 1a. In addition, a threshold voltage related to the key K2=512 is set to each transistor of the second string 1b, and the voltage related to the query Q1=3 is applied to the gate of each transistor of the second string 1b. In addition, the threshold voltage related to the key K1=3 is set to each transistor of the third string 1c, and a voltage related to the query Q2=512 is applied to the gate of each transistor of the third string 1c. In addition, the threshold voltage related to the key K2=512 is set to each transistor of the fourth string 1d, and the voltage related to the query Q2=512 is applied to the gate of each transistor of the fourth string 1d.

In the first example, since the key and the query match in each of the first string 1a and the fourth string 1d, a current flows through each of the first string 1a and the fourth string 1d. Since the key and the query do not match in each of the second string 1b and the third string 1c, no current flows through the second string 1b and the third string 1c. Therefore, a current about twice the current flowing through the first string 1a or the fourth string 4b flows through the bit line to which the first to fourth strings 1a to 1d are connected.

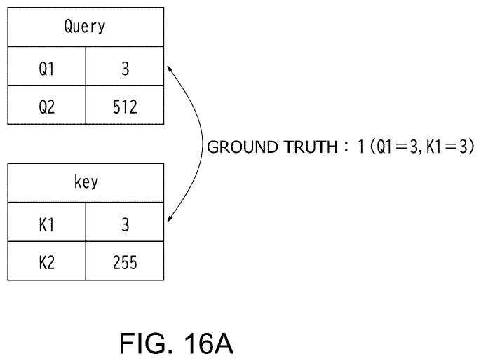

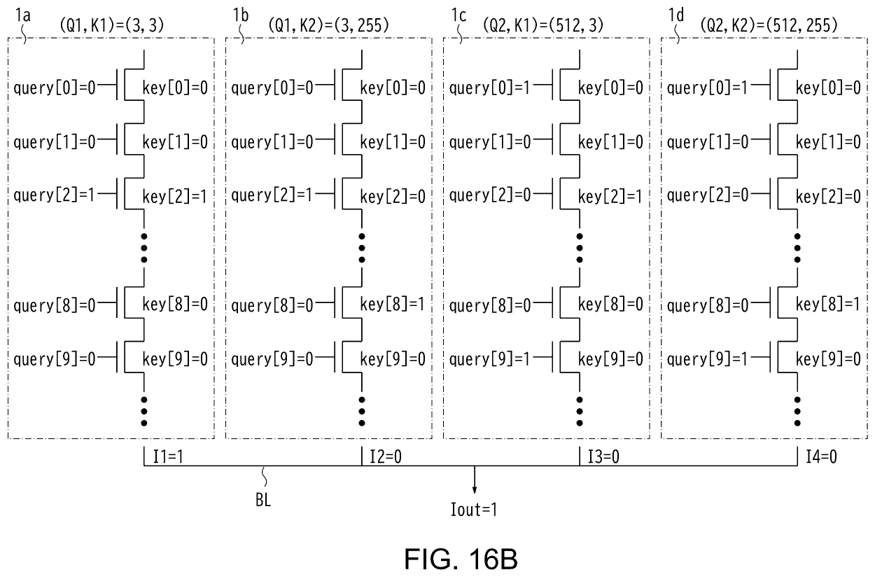

In the second example of FIGS. 16A and 16B, the key has valid values of 3 and 255 and the query has valid values of 3 and 512. This is expressed as (Q1, Q2)=(3, 512) and (K1, K2)=(3, 255) in the present specification. FIG. 16A is a diagram illustrating values of the query (Q1, Q2) and the key (K1, K2) input and set to the four strings 1 according to the second example. FIG. 16B is a circuit diagram of the four strings 1 according to the second example in which the query (Q1, Q2) and the key (K1, K2) in FIG. 16A are input and set. As illustrated in FIG. 16A, since each of the key and the query has two valid values in the second example, all combinations of the key and the query are (Q1, K1)=(3, 3), (Q1, K2)=(3, 255), (Q2, K1)=(512, 3), and (Q2, K2)=(512, 255).

In the second example, (Q1, K1)=(3, 3) is compared in the first string 1a, (Q1, K2)=(3, 255) is compared in the second string 1b, (Q2, K1)=(512, 3) is compared in the third string 1c, and (Q2, K2)=(512, 255) is compared in the fourth string 1d.

As illustrated in FIG. 16B, in the second example, a threshold voltage related to the key K1=3 is set to each transistor of the first string 1a, and a voltage related to the query Q1=3 is applied to the gate of each transistor of the first string 1a. In addition, a threshold voltage related to the key K2=255 is set to each transistor of the second string 1b, and the voltage related to the query Q1=3 is applied to the gate of each transistor of the second string 1b. In addition, the threshold voltage related to the key K1=3 is set to each transistor of the third string 1c, and a voltage related to the query Q2=512 is applied to the gate of each transistor of the third string 1c. In addition, the threshold voltage related to the key K2=255 is set to each transistor of the fourth string 1d, and the voltage related to the query Q2=512 is applied to the gate of each transistor of the fourth string 1d.

In the second example, since the key and the query match in the first string 1a, a current flows through the first string 1a. In the second to fourth strings 1b to 1d, since the key and the query do not match, no current flows through the second to fourth strings 1b to 1d. Therefore, the current flowing through the first string 1a flows through the bit line to which the first to fourth strings 1a to 1d are connected.

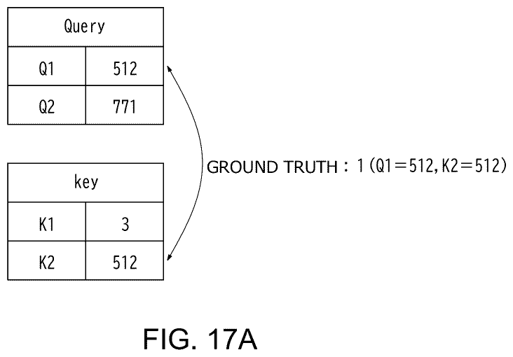

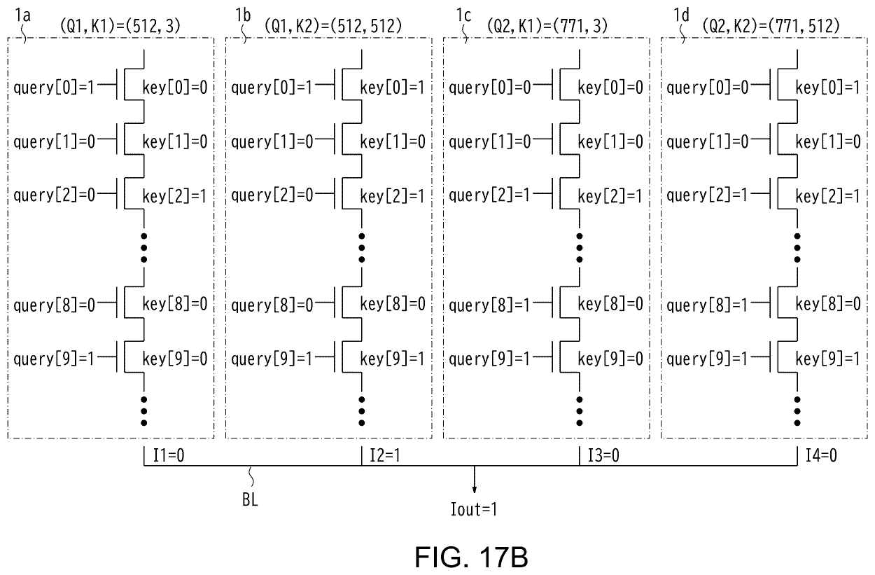

In the third example of FIGS. 17A and 17B, the key has valid values of 3 and 512 and the query has valid values of 512 and 771. This is expressed as (Q1, Q2)=(512, 771) and (K1, K2)=(3, 512) in the present specification. FIG. 17A is a diagram illustrating values of the query (Q1, Q2) and the key (K1, K2) input and set to the four strings 1 according to the third example. FIG. 17B is a circuit diagram of the four strings 1 according to the third example in which the query (Q1, Q2) and the key (K1, K2) in FIG. 17A are input and set. As illustrated in FIG. 17A, since each of the key and the query has two valid values in the third example, all combinations of the key and the query are (Q1, K1)=(512, 3), (Q1, K2)=(512, 512), (Q2, K1)=(771, 3), and (Q2, K2)=(771, 512).

In the third example, (Q1, K1)=(512, 3) is compared in the first string 1a, (Q1, K2)=(512, 512) is compared in the second string 1b, (Q2, K1)=(771, 3) is compared in the third string 1c, and (Q2, K2)=(771, 512) is compared in the fourth string 1d.

As illustrated in FIG. 17B, in the third example, a threshold voltage related to the key K1=3 is set to each transistor of the first string 1a, and a voltage related to the query Q1=512 is applied to the gate of each transistor of the first string 1a. In addition, a threshold voltage related to the key K2=512 is set to each transistor of the second string 1b, and the voltage related to the query Q1=512 is applied to the gate of each transistor of the second string 1b. In addition, the threshold voltage related to the key K1=3 is set to each transistor of the third string 1c, and a voltage related to the query Q2=771 is applied to the gate of each transistor of the third string 1c. In addition, the threshold voltage related to the key K2=512 is set to each transistor of the fourth string 1d, and the voltage related to the query Q2=771 is applied to the gate of each transistor of the fourth string 1d.

In the third example, since the key and the query match in the second string 1b, a current flows through the second string 1b. In the first, third, and fourth strings 1a, 1c, and 1d, since the key and the query do not match, no current flows through the first, third, and fourth strings 1a, 1c, and 1d. Therefore, the current flowing through the second string 1b flows through the bit line to which the first to fourth strings 1a to 1d are connected.

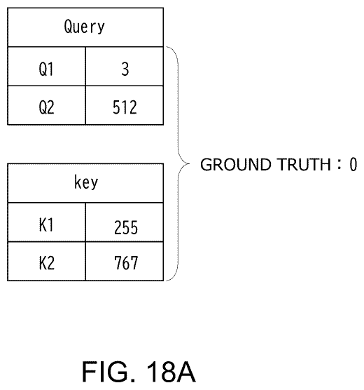

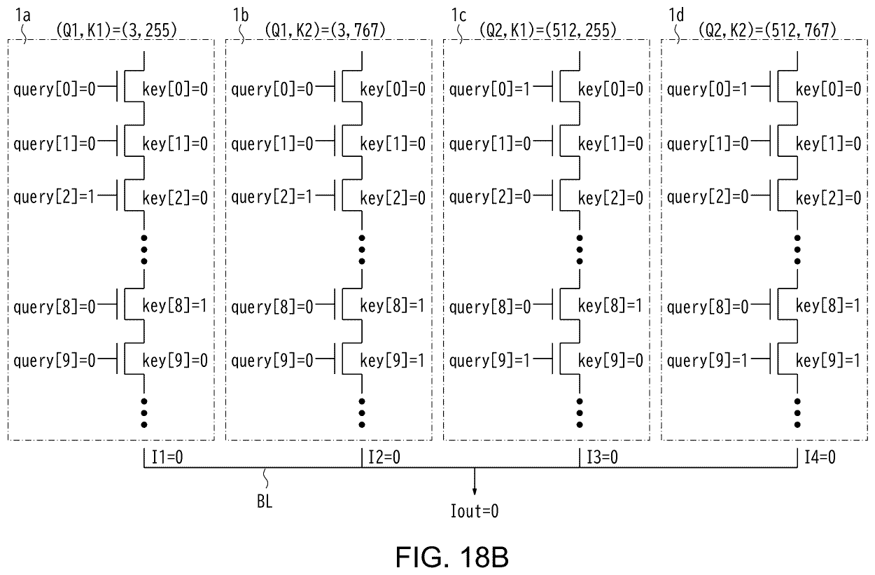

In the fourth example of FIGS. 18A and 18B, the key has valid values of 255 and 767, and the query has valid values of 3 and 512. This is expressed as (Q1, Q2)=(3, 512) and (K1, K2)=(255, 767) in the present specification. FIG. 18A is a diagram illustrating values of the query (Q1, Q2) and the key (K1, K2) input and set to the four strings 1 according to the fourth example. FIG. 18B is a circuit diagram of the four strings 1 according to the fourth example in which the query (Q1, Q2) and the key (K1, K2) in FIG. 18A are input and set. As illustrated in FIG. 18A since each of the key and the query has two valid values in the fourth example, all combinations of the key and the query are (Q1, K1)=(3, 255), (Q1, K2)=(3, 767), (Q2, K1)=(512, 255), and (Q2, K2)=(512, 767).

In the fourth example, (Q1, K1)=(3, 255) is compared in the first string 1a, (Q1, K2)=(3, 767) is compared in the second string 1b, (Q2, K1)=(512, 255) is compared in the third string 1c, and (Q2, K2)=(512, 767) is compared in the fourth string 1d.

As illustrated in FIG. 18B, in the fourth example, a threshold voltage related to the key K1=255 is set to each transistor of the first string 1a, and a voltage related to the query Q1=3 is applied to the gate of each transistor of the first string 1a. In addition, a threshold voltage related to the key K2=767 is set to each transistor of the second string 1b, and the voltage related to the query Q1=3 is applied to the gate of each transistor of the second string 1b. In addition, the threshold voltage related to the key K1=255 is set to each transistor of the third string 1c, and a voltage related to the query Q2=512 is applied to the gate of each transistor of the third string 1c. In addition, the threshold voltage related to the key K2=767 is set to each transistor of the fourth string 1d, and the voltage related to the query Q2=512 is applied to the gate of each transistor of the fourth string 1d.

In the fourth example, since the key and the query do not match in any of the first to fourth strings 1a to 1d, no current flows through any of the first to fourth strings 1a to 1d.

As illustrated in the first to fourth examples of FIGS. 15A to 18B, in a case where the inner product operation of two compressed vectors corresponding to two sparse vectors each including two valid values is performed, by providing 2×2=4 strings 1 and performing the inner product operation for all combinations of two keys (two compressed vectors) and two queries (two compressed vectors) each including one valid value in each of the strings 1, it is possible to carry a current based on an inner product value of the two keys and the two queries through a bit line to which the four strings 1 are connected.

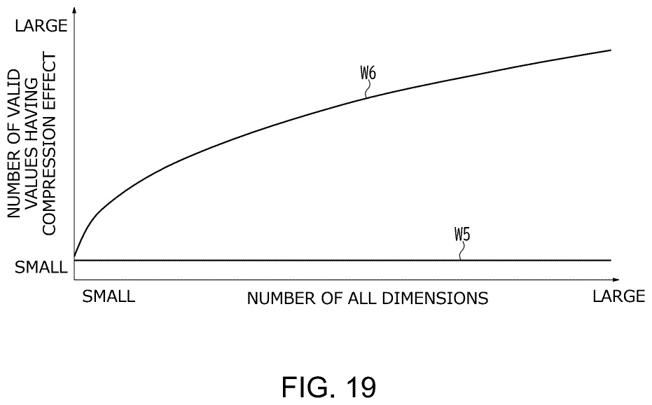

FIG. 19 is a view illustrating a correspondence relationship between the number of all dimensions of a key and a query and the number of valid values included in the key and the query. In FIG. 19, the horizontal axis represents the number of dimensions of sparse vectors of the key and the query, and the vertical axis represents the number of valid values included in sparse vectors that enable the inner product operation. FIG. 19 illustrates a correspondence relationship W5 in a case where the inner product operation is performed with the key and the query as the sparse vectors, and a correspondence relationship W6 in a case where the inner product operation is performed with a key and a query as compressed vectors.

When the inner product operation of the key and the query is performed directly using the sparse vectors, the number of valid values does not increase even if the number of dimensions increases as illustrated in the correspondence relationship W5. On the other hand, when the sparse vectors are converted into the compressed vectors to perform the inner product operation of the key and the query, if the number of dimensions increases, the number of valid values can also be increased accordingly as illustrated in the correspondence relationship W6, and the inner product operation can be performed between the sparse vectors including more valid values.

The correspondence relationship W6 can be represented by the following Formula (1). In Formula (1), dim is the number of all dimensions, and y_{enable} is the number of valid values with which the inner product operation can be correctly performed.

$${y}_{e n a b l e} = \sqrt{\frac{dim + 1}{{log}_{2} ( dim + 1 )}} \qquad ( 1 )$$

As described above, in the information processing apparatus according to the embodiment, the number of strings 1 used for the inner product operation changes according to the number of valid values included in each sparse vector of the key and the query. Specifically, the memory area including the strings 1 as many as the square of the number of valid values is secured on the memory cell array.

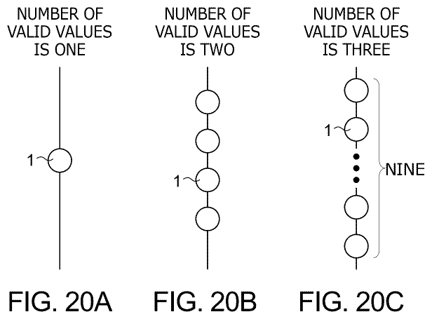

FIGS. 20A, 20B, and 20C are diagrams each illustrating the memory area including the string 1 secured on the memory cell array according to the number of valid values included in each sparse vector of a key and a query. When the number of valid values is 1, the inner product operation can be performed in the memory area including one string 1 as illustrated in FIG. 20A. When the number of valid values is 2, the inner product operation can be performed in the memory area including 2×2=4 strings 1 as illustrated in FIG. 20B. When the number of valid values is 3, the inner product operation can be performed in the memory area including 3×3=9 strings 1 as illustrated in FIG. 20C.

As described above, the larger the number of valid values, the larger the memory area required for the inner product operation. As a method of reducing the memory area, the inner product operation may be performed in a time-division manner by using a limited number of strings 1 a plurality of times.

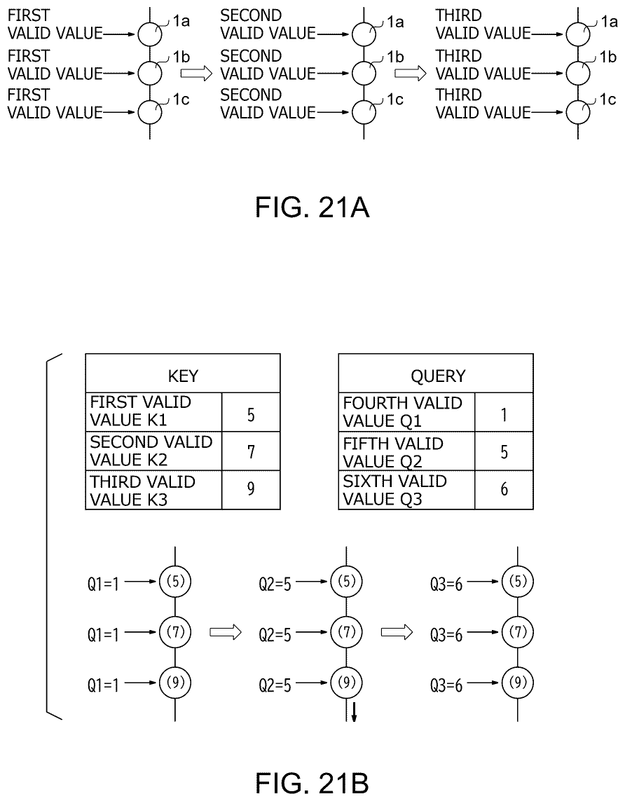

FIGS. 21A and 21B are diagrams for describing an example in which the inner product operation is performed in a time-division manner by using a limited number of strings 1 a plurality of times. For example, the strings 1 as many as the number of valid values included in sparse vectors of keys are provided. As an example, when the sparse vectors of the keys include three valid values, three strings 1 (first to third strings 1a, 1b, and 1c) are provided. The strings 1 are provided for the valid values, respectively. For example, assuming that the three valid values included in the sparse vectors of the keys are first to third valid values, a threshold voltage of each transistor of the first string 1a is set based on a compressed vector corresponding to a sparse vector including only the first valid value. In addition, a threshold voltage of each transistor of the second string 1b is set based on a compressed vector corresponding to a sparse vector including only the second valid value. In addition, the threshold voltage of each transistor of the third string 1c is set based on a compressed vector corresponding to a sparse vector including only the third valid value.

It is assumed that sparse vectors of queries include three valid values, and these valid values are set as fourth to sixth valid values.

In the inner product operation performed for the first time illustrated in FIG. 21A, a voltage based on a compressed vector corresponding to a sparse vector including only the fourth valid value is applied to a gate of each transistor of the first to third strings 1a, 1b, and 1c. As a result, the sum of currents flowing through the first to third strings 1a, 1b, and 1c flows through a bit line. The sense amplifier stores a current flowing through the bit line as a result of the first inner product operation.

In the inner product operation performed for the second time illustrated in FIG. 21A, a voltage based on a compressed vector corresponding to a sparse vector including only the fifth valid value is applied to the gate of each transistor of the first to third strings 1a, 1b, and 1c. As a result, the sum of currents flowing through the first to third strings 1a, 1b, and 1c flows through the bit line. The sense amplifier stores a current flowing through the bit line as a result of the second inner product operation.

In the inner product operation performed for the third time illustrated in FIG. 21A, a voltage based on a compressed vector corresponding to a sparse vector including only the sixth valid value is applied to the gate of each transistor of the first to third strings 1a, 1b, and 1c. As a result, the sum of currents flowing through the first to third strings 1a, 1b, and 1c flows through the bit line. The sense amplifier stores a current flowing through the bit line as a result of the third inner product operation.

The sense amplifier calculates an inner product value based on the sum of the currents flowing through the bit line for the first to third times.

FIG. 21B is a diagram illustrating an example in which FIG. 21A is further embodied. FIG. 21B illustrates an example in which the key has a first valid value K1=5, a second valid value K2=7, and a third valid value K3=9, and the query has a fourth valid value Q1=1, a fifth valid value Q2=5, and a sixth valid value Q3=6.

In the first inner product operation illustrated in FIG. 21B, a voltage based on a compressed vector corresponding to a sparse vector including only the fourth valid value Q1=1 is applied to the gate of each transistor of the first to third strings 1a, 1b, and 1c. As a result, the sum of currents flowing through the first to third strings 1a, 1b, and 1c flows through the bit line. In this case, since the query and the key do not match in any of the first to third strings 1a, 1b, and 1c, no current flows through the bit line.

In the second inner product operation illustrated in FIG. 21B, a voltage based on a compressed vector corresponding to a sparse vector including only the fifth valid value Q2=5 is applied to the gate of each transistor of the first to third strings 1a, 1b, and 1c. As a result, the sum of currents flowing through the first to third strings 1a, 1b, and 1c flows through the bit line. In this case, since the query K1=5 and the key Q2=5 match in the first string 1a, a current flows through the first string 1a and the bit line.

In the third inner product operation illustrated in FIG. 21B, a voltage based on a compressed vector corresponding to a sparse vector including only the sixth valid value Q3=6 is applied to the gate of each transistor of the first to third strings 1a, 1b, and 1c. As a result, the sum of currents flowing through the first to third strings 1a, 1b, and 1c flows through the bit line. In this case, since the query and the key do not match in any of the first to third strings 1a, 1b, and 1c, no current flows through the bit line.

As described above, in the examples of FIGS. 21A and 21B, since the inner product operation of the key and the query can be performed with the strings 1 as many as the number of valid values included in the sparse vectors of the keys, the number of the strings 1 used for the inner product operation can be greatly reduced.

Although an example in which the memory area including the number of the strings 1 corresponding to the number of valid values is secured has been illustrated in FIGS. 20, 21A, and 21B, the memory area for a plurality of strings 1 corresponding to a predetermined number may be secured regardless of the number of valid values.

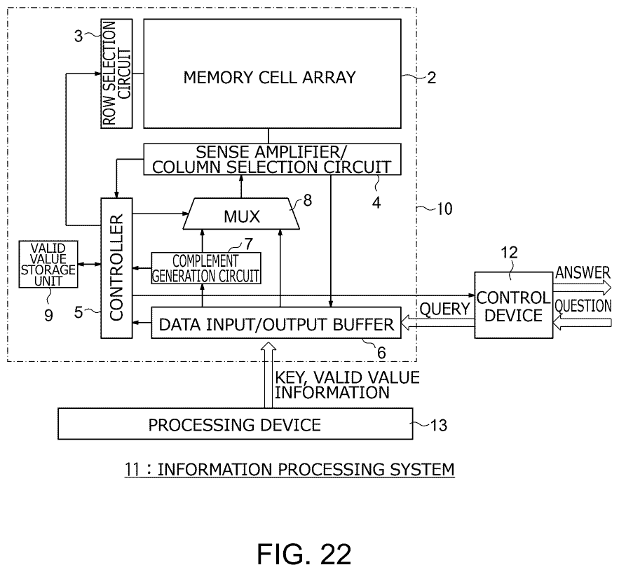

FIG. 22 is a block diagram illustrating a schematic configuration of an information processing system 11 including an information processing apparatus 10 according to an embodiment. The information processing system 11 includes the information processing apparatus 10 according to the embodiment, a control device (control unit) 12, and a processing device 13. The information processing apparatus 10 and the control device 12 constitute a memory system.

The control device 12 converts an input question into a query, and generates an answer to the question based on an inner product value obtained by the information processing apparatus 10.

The question and the answer are, for example, statements or sentences including words and vocabularies used by humans in daily life.

The processing device 13 performs natural language processing on a huge number of sentences including words and vocabularies to generate a large number of sparse vectors, and learns the number of valid values included in the sparse vectors and keys. Since the learning of the processing device 13 is likely to require enormous arithmetic capacity, for example, a server device accessible by the information processing apparatus 10 via a network may be used as the processing device 13.

The processing device 13 inputs compressed vectors corresponding to sparse vectors of the learned keys and the number of valid values included in the learned sparse vectors to the information processing apparatus 10.

The information processing apparatus 10 includes a memory cell array 2, a row selection circuit 3, a sense amplifier/column selection circuit 4, a controller 5, a data input/output buffer (acquisition unit) 6, a complement generation circuit 7, a multiplexer (MUX) 8, and a valid value storage unit 9.

The memory cell array 2 has a plurality of the strings 1 connected to the same bit line BL as described above. A plurality of the bit lines BL may be arranged in the memory cell array 2. In this case, the plurality of strings 1 similar to those in FIG. 3 are provided for each bit line BL. Similarly to FIG. 3, each of the strings 1 includes a first transistor Q1 and a second transistor Q2, and the word line WL set to a potential level corresponding to the query Q is connected to each gate of the first transistor Q1 and the second transistor Q2.

As illustrated in FIG. 3, a plurality of transistors may be cascode-connected to each of the strings 1 in addition to the first transistor Q1 and the second transistor Q2. The plurality of transistors are set to an ON state when a current of the string 1 is read.

The row selection circuit 3 sets the potential level of the word line WL connected to each gate of the first transistor Q1 and the second transistor Q2 according to the query Q supplied from the outside in accordance with an instruction from the controller 5.

The data input/output buffer 6 acquires the key K from the processing device 13, and supplies the acquired key K to the complement generation circuit 7 and the multiplexer 8 in accordance with an instruction from the controller 5. The complement generation circuit 7 inverts the key K from the data input/output buffer 6 for each bit to generate complement data of the key K. In accordance with an instruction from the controller 5, the multiplexer 8 selects either the key K from the data input/output buffer 6 or the complement data of the key K generated by the complement generation circuit 7, and supplies the selected one to the sense amplifier/column selection circuit 4. Note that the complement generation circuit 7 and the multiplexer may be similarly provided on the row selection circuit 3 side to which an address (query) is input. In accordance with an instruction from the controller 5, the multiplexer 8 selects either the key input from the processing device 13 via the data input/output buffer 6 or the complement data of the key generated by the complement generation circuit 7 and inputs the selected one to the sense amplifier/column selection circuit 4. In addition, the controller 5 supplies the query input from the control device 12 via the data input/output buffer 6 and complement data of the query generated by the complement generation circuit 7 to the row selection circuit 3.

The sense amplifier/column selection circuit 4 supplies the key K or the complement data output from the multiplexer 8 to the bit line BL. In addition, the sense amplifier/column selection circuit 4 senses a current flowing from the string 1 to the bit line.

The controller 5 obtains an inner product value based on the current sensed by the sense amplifier/column selection circuit 4. The controller 5 performs match search as to whether the query and the key match based on the inner product value. Alternatively, the controller 5 performs approximate nearest neighbor search of the query and the key based on the inner product value. A result of the match search or the approximate nearest neighbor search is sent to the control device 12.

The control device 12 generates and outputs the answer to the question based on the result of the match search or the approximate nearest neighbor search.

The valid value storage unit 9 stores the valid values included in the learned sparse vectors input from the processing device 13. As described above, the controller 5 secures, on the memory cell array, a memory area of the strings 1 as many as the square of the number of valid values stored in the valid value storage unit 9 for the inner product operation.

Note that the processing device 13 may input a value of the square of the number of valid values to the information processing apparatus 10. In this case, the valid value storage unit 9 stores the value of the square of the number of valid values.

As described above, in the information processing apparatus 10 according to the embodiment, in a case where a plurality of valid values are included in each of two sparse vectors of a key and a query, the number of the strings 1 corresponding to the number of the valid values is secured on the memory cell array, and the inner product operation is performed using a plurality of the secured strings 1 for all combinations of a plurality of compressed vectors each including one valid value of the key and a plurality of compressed vectors each including one valid value of the query. As a result, an inner product value can be correctly calculated even when the plurality of valid values are included in the sparse vectors of the key and the query.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. An information processing apparatus comprising
a plurality of strings connected to a first wiring and respectively connected to a plurality of second wirings, the plurality of strings being configured to perform an inner product operation of first data and second data each including a plurality of bits,
wherein each of the plurality of strings includes a plurality of transistors connected in series,
a threshold voltage based on the first data is set to the plurality of transistors,
a voltage based on the second data is applied to each of gates of the plurality of transistors via a corresponding second wiring among the second wirings,
two or more bits included in each of the first data and the second data are valid values other than 0, and
each of the plurality of strings carries a current based on an inner product value of the first data respectively including different ones of the valid values and the second data respectively including different ones of the valid values to the first wiring.

2. The information processing apparatus according to claim 1, wherein
a sum of the current flowing through each of the plurality of strings flows through the first wiring as the inner product value.

3. The information processing apparatus according to claim 1, wherein
the plurality of transistors include a plurality of sets each including a first transistor and a second transistor,
threshold voltages having a complementary relationship with each other are set to the first transistor and the second transistor of each set based on the first data, and
voltages having a complementary relationship with each other are applied to gates of the first transistor and the second transistor of each set based on the second data.

4. The information processing apparatus according to claim 3, wherein
the threshold voltages based on a corresponding bit value of the first data and an inverted bit value of the corresponding bit value of the first data are set to the first transistor and the second transistor of each set, and
the voltages based on a corresponding bit value of the second data and an inverted bit value of the corresponding bit value of the second data are applied to the gates of the first transistor and the second transistor of each set.

5. The information processing apparatus according to claim 1, wherein
a number of the plurality of strings is the number corresponding to a number of the valid values.

6. The information processing apparatus according to claim 5, wherein
each of the first data and the second data includes an identical number of the valid values.

7. The information processing apparatus according to claim 5, wherein
the number of the plurality of strings is square of n when the number of the valid values is n (n is an integer of 2 or more).

8. The information processing apparatus according to claim 5, wherein
a memory area including a number of a plurality of strings corresponding to the number of valid values is provided in the memory cell array, and
the inner product value of the first data and the second data is obtained by a one-time current flowing through the plurality of strings.

9. The information processing apparatus according to claim 5, wherein
a memory area including a predetermined number of plurality of strings, the number being regardless of the number of the valid values, is provided in a memory cell array, and
the inner product value of the first data and the second data is obtained by a one-time current flowing through the plurality of strings.

10. The information processing apparatus according to claim 5, wherein
the plurality of strings carries the currents based on a plurality of the inner product values in all combinations of pieces of the first data corresponding to the number of valid values and pieces of the second data corresponding to the number of valid values to the first wiring.

11. The information processing apparatus according to claim 1, wherein
a memory area including a number of plurality of strings corresponding to the number of valid values is provided in the memory cell array, and
the inner product value of the first data and the second data is obtained by a sum of currents flowing through the plurality of strings over a plurality of times.

12. The information processing apparatus according to claim 11, wherein
the memory area including a number of plurality of strings corresponding to the number of valid values is provided in the memory cell array, and
the inner product value of the first data and the second data is obtained by a sum of a plurality of times of currents flowing through the plurality of strings.

13. The information processing apparatus according to claim 12, wherein
a memory area including the plurality of strings as many as the number of the valid values is provided in the memory cell array.

14. The information processing apparatus according to claim 12, wherein
a threshold voltage based on the valid value different for each of the plurality of strings is set to the plurality of transistors, and
a voltage based on the valid value, common to the plurality of strings and different for each time, is applied to each of the gates of the plurality of transistors.

15. The information processing apparatus according to claim 1, wherein
each of the first data and the second data is a compressed vector including a plurality of bits representing, in binary numbers, bit positions of the valid values in a sparse vector including bits of 0 other than the valid values.

16. The information processing apparatus according to claim 1, further comprising
a nonvolatile memory including the plurality of strings,
wherein the first wiring is a bit line, and
the second wiring is a word line.

17. The information processing apparatus according to claim 16, wherein
the nonvolatile memory is a NAND flash memory.

18. An information processing system comprising:
the information processing apparatus according to claim 1; and
a control device configured to convert an input question into the second data and generate an answer to the question based on the inner product value obtained by the information processing apparatus,
wherein the information processing apparatus includes
an acquisition unit configured to acquire the first data, a number of strings to be used, and the second data, and
a control unit configured to perform match search or approximate nearest neighbor search of the first data and the second data based on the inner product value of the first data and the second data.
